(19) United States
(12) Patent Application Publication
(10) Pub. No.: US 2007/0068802 A1
(43) Pub. Date: Mar. 29, 2007

(54) Substrate carrier

(76) Inventors: Thomas Gebele, Freigericht (DE); Oliver Heimel, Wabern (DE); Thomas Klug, Grossostheim (DE)

Correspondence Address: FULBRIGHT & JAWORSKI, LLP, 666 FIFTH AVE, NEW YORK, NY, 10103-3198, US

(21) Appl. No.: 11/254,427

(22) Filed: Oct. 20, 2005

(30) Foreign Application Priority Data
Sep. 24, 2005 (DE) 10 2005 045 717.7

(51) Int. Cl. C23C 14/00

(52) U.S. Cl. 204/298.02

(57) ABSTRACT

The invention relates to a substrate carrier comprising two vertical plates and two horizontal plates. In order for the substrate during its transport through a sputter unit to be coated uniformly in its margin regions, a lever arrangement is provided between the two vertical plates. The lever arrangement comprises at least one horizontal web which under the effect of heat expands to a lesser degree than the horizontal plates.

### FIELD OF THE INVENTION

This application claims priority from German Patent application No. 10 2005 045 717.7 filed Sep. 24, 2005, incorporated herein by reference in its entirety.

The invention relates to a substrate carrier.

### BACKGROUND AND SUMMARY OF THE INVENTION

Substrates are often guided in sputter units past a so-called target, from the surface of which particles are sputtered off, which are subsequently deposited on the substrate. As the substrates can be utilized, for example, glass plates, which are transported through an inline sputter unit. These glass plates are set into a frame connected with a transport device.

A device for the transport of substrates into and through vacuum treatment units, for example, is known, which comprises a bulky foot part composed of two wheel sets correlated with one track and one support bearing (DE 41 39 549 A1). The substrates to be treated are herein held by means of a rectangular substrate holder.

Furthermore is known an annular substrate holder for the mounting of a round substrate plate, this substrate holder, in turn, being held by four equally distributed holding arms (DE 102 11 827 C1).

If the substrates held in frames have a coefficient of thermal expansion different from that of the frames, the substrates may be covered at the margins nonuniformly and onesidedly to too high a degree. In the case of wafers this is referred to as “edge exclusion”, i.e. to a peripheral region of the wafer which is not coated.

The invention therefore addresses the problem of providing a carrier for substrates, in which the substrate are not covered too thickly at the margin and the coverage on both margins is substantially equal.

This problem is solved according to the present invention, which relates in part to a carrier for a substrate comprising two vertical plates and two horizontal plates. In order for the substrate not to be coated nonuniformly in its margin regions during its transport through a sputter unit, a lever arrangement is provided between the two vertical plates. The lever arrangement comprises at least one horizontal web which expands to a lesser degree under the effect of heat than the horizontal plates.

The advantage attained with the invention resides in particular therein that with the aid of a lever arrangement, which exploits the effect of the difference in the coefficients of thermal expansion, the substrates to be coated are held symmetrically relative to the carrier frame.

An embodiment example of the invention is shown in the drawing and will be described in further detail below.

### BRIEF DESCRIPTION OF THE FIGURES

FIG. 1 shows a first embodiment of the invention.

FIG. 2 shows a second embodiment of the invention.

### DETAILED DESCRIPTION

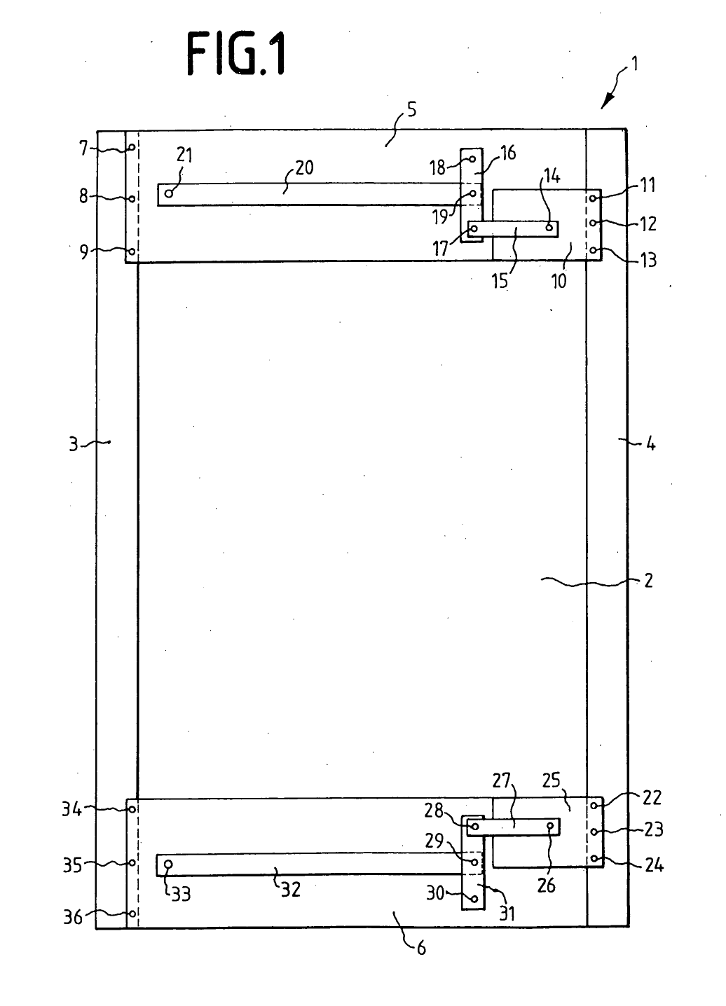

FIG. 1 depicts a carrier 1 for a substrate 2, which comprises a frame with two vertical plates 3, 4 and two horizontal plates 5, 6. The plates 3, 4 are comprised, for example, of titanium, while the plates 5, 6 are comprised, for example, of aluminum.

The left end of the upper aluminum plate 5 is connected with the titanium plate 3 by means of bolts 7, 8, 9 or other connection elements.

The right end of the aluminum plate 5 is not directly connected with the titanium plate 4 but rather indirectly via a small aluminum plate 10. This small aluminum plate 10 is connected with its right end by means of three bolts 11, 12, 13 or the like with the titanium plate 4. At ambient temperature there is a gap between the plate 4 and the aluminum plates 5, 6, which is closed at sputter temperatures. Consequently, FIG. 1 shows a carrier during sputter operation.

By means of a bolt 14 or the like approximately in the center of the small aluminum plate 10 a rotatable connection is established between the small aluminum plate 10 and the right end of a web 15 of titanium. Instead of a bolt 14, a pin, stud or the like can be utilized, which holds together two parts and makes possible their relative movement or rotational movement. There is no fixed connection between the small aluminum plate 10 and the large aluminum plate 5. The aluminum plate 10 is only guided in the aluminum plate 5. The left end of the titanium web 15 is rotatably connected with the lower end of a perpendicularly extending web 16 by means of a bolt 17 or the like, which does not extend through the aluminum plate 5. A rotatable connection between this aluminum plate 5 and the upper end of web 16 is established by means of a bolt 18 or the like. The vertical web 16 does not necessarily need to comprise titanium, it can also be produced for example of steel or another metal.

Via a bolt 19 or the like in the center of vertical web 16 a connection has been established between this web 16 and the right end of a horizontally extending further web 20, not, however, with plate 5. The left end of web 20 is directly connected with plate 5 via a bolt 21 or the like. However, a direct connection between plate 3 and web 20 could also be provided.

Mirror symmetrically to the structural parts located on the upper plate 5 are also disposed the corresponding structural parts on the lower plate. Therefore, bolt 26 corresponds to bolt 14.

The small aluminum plates 10, 25 can each move horizontally on the large aluminum plates 5, 6, since they only rest in contact on them or are guided in them.

With the aid of the lever arrangements formed by webs 15, 16, 20 and 27, 31, 32, respectively, it is possible to keep the distance between plates 3, 4 constant.

The manner in which this is specifically achieved will be described in the following.

If it is assumed that the device depicted in FIG. 1 is brought from approximately ambient temperature to a temperature increased by approximately 220° C. as is customary during sputtering, all parts comprised of aluminum expand to a high degree, while the parts comprised of titanium expand to a lesser degree.

Consequently a relative movement between the individual parts occurs, which essentially results in a relative movement between the small aluminum plates 10 and 25 with respect to the large aluminum plates 5, 6. In effect, the small aluminum plates 10 and 25 pull the plate 4 relatively to the left, such that the original distance from plate 3 is maintained.

With an increase of the temperature the aluminum plates 5, 6 expand to a high degree. The gaps previously existing between the aluminum plates 5, 6 and plate 4 are hereby closed. Since the horizontal titanium webs 20, 32 are connected with the large aluminum plates 5, 6 in points 21, 33, these titanium webs 20, 32 move with the aluminum plates 5, 6 to the right. They therewith would rotate the webs 16, 31 about the pivot points 18, 30 in the counterclockwise direction or the clockwise direction, which are fixedly connected in these pivot points 18, 30 with the aluminum plates 5, 6, if they were to have a coefficient of thermal expansion corresponding to the coefficients of thermal expansion corresponding to the plates 5, 6. Therewith the small aluminum plates 10, 25 would be pushed away toward the right via the webs 15, 27, i.e. they would slide over the large aluminum plates 5, 6. However, points 18 and 30 themselves have shifted considerably toward the right, since they are connected with the plates 5, 6. Consequently, the web 16 does not rotate in the counterclockwise direction, but rather in the clockwise direction, since point 19 relative to point 18 is retained in position by titanium web 20, while point 18 migrates toward the right. The displacement of points 30 and 18 to the right is herein approximately three times as large as that of points 29 or 19, respectively. In contrast, web 20, 32, since it is comprised of titanium, has expanded only minimally toward the right and retains points 19 or 29 nearly in their original position.

As a consequence the upper web 16 is not rotated about point 18 in the counterclockwise direction, but rather in the clockwise direction. The lower web 31 conversely is not rotated about point 30 in the clockwise direction, but rather in the counterclockwise direction.

The small aluminum plates 10, 25 are therewith shifted to the left and over plates 5, 6. Since they are coupled with plate 4, the latter is also shifted to the left. Therewith the gap previously formed between plate 4 and the small aluminum plates 10, 25 is closed. With the appropriate layout of the ratios of the lengths between the points 30, 29 and 28, the distance between the titanium plates 3, 4 can be kept constant.

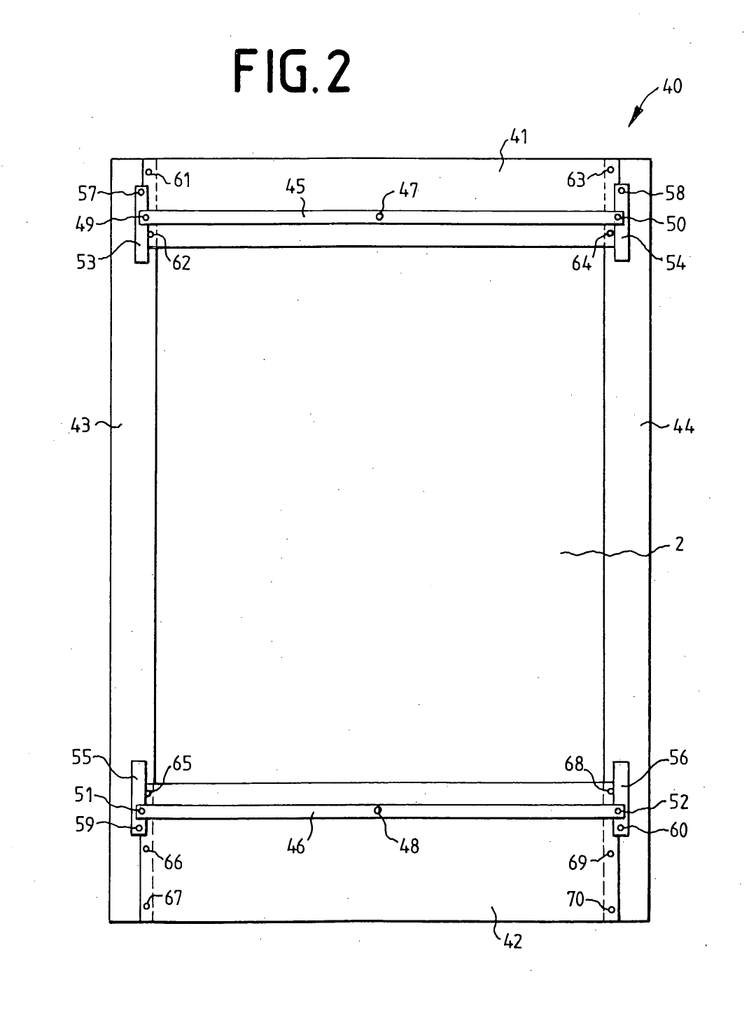

FIG. 2 shows a second variant of the invention, which includes a frame 40 for the transport of a substrate 2. This frame 40 is comprised of two large horizontal aluminum plates 41, 42 and two vertical titanium plates 43, 44. Centrally on the large aluminum plates 41, 42 are disposed titanium webs 45, 46, which are connected with these aluminum plates 41, 42 by means of connection elements 47, 48 in their center. These titanium webs 45, 46 are rotatably connected at their ends with levers 53 to 56 via connection elements 49 to 52. These levers 53 to 56 are, in turn, rotatably connected with plates 43 or 44 via connection elements 57 to 60. Ends of the aluminum plates 41, 42 are also connected with these plates 43, 44 via connection elements 61 to 70.

When the frame 40 is heated during the sputtering, the parts comprised of aluminum expand to a greater degree than the parts comprised of titanium. This means that the aluminum plates 41, 42 expand horizontally to a greater degree than the titanium plates 43, 44 or the titanium webs 45, 46.

The levers 53 to 56 are hereby rotated about points 57 to 60 in the direction toward the substrate 2. On the one hand, the aluminum plates 41, 42 press plates 43, 44 apart, on the other hand, the ends of levers 53 to 56 remain in contact on the substrate, since, due to the lesser thermal expansion of webs 45, 46, these levers 53 to 56 are in effect retained in their position in their center and must rotate inwardly about points 57 to 60.

In spite of the tendency of the plates 43, 44 to move away from each other, the substrate 2 consequently continues to be retained through levers 53 to 56.

In the above described embodiment examples the materials titanium and aluminum were discussed. However, other materials can also be utilized. Aluminum is employed since it is relatively cost-effective. Titanium, which is significantly more expensive than aluminum, is employed since it has a lower coefficient of thermal expansion than aluminum.

It is understood that the terms “vertical’ and “horizontal” can also be interchanged.

1-8. (canceled)

9. A carrrier for a substrate comprising
two vertical plates; and two horizontal plates and a lever arrangement between the two vertical plates, which includes at least one web whose coefficient of thermal expansion is lower than the coefficient of thermal expansion of the horizontal plates.

10. The carrier as claimed in claim 9, wherein the horizontal plates are fixedly connected with one of their ends with one of the vertical plates.

11. The carrier as claimed in claim 9, wherein on each of the horizontal plates resides a small plate one of the ends of which is connected with the other vertical plate.

12. The carrier as claimed in claim 9, wherein the one web is connected at its one end with a horizontal plate.

13. The carrier as claimed in claim 9, wherein the one web with its other end is connected with a vertical web.

14. The carrier as claimed in claim 13, wherein the vertical web is connected with one of its ends with a horizontal plate.

15. The carrier as claimed in claim 9, wherein the vertical web is rotatably connected at its other end with a horizontal web, which, in turn, is connected with the small plate, which is connected with one side with the vertical plate.

16. The carrier as claimed in claim 9, wherein the lever arrangement includes a horizontally extending web, which is connected with its ends with a web, which, in turn, is rotatably connected with one end with a vertical plate.
